(19) United States
(12) Patent Application Publication
(10) Pub. No.: US 2003/0011425 A1
(43) Pub. Date: Jan. 16, 2003

(54) Injection current test circuit

(75) Inventor: Kevin Scott Buescher, Colorado Springs, CO (US)

Correspondence Address: Law Offices of Dale B. Halling, 24 South Weber St., Suite 311, Colorado Springs, CO, 80903, US

(73) Assignee: EM Microelectronics - US Inc.

(21) Appl. No.: 09/903,929

(22) Filed: Jul. 12, 2001

(51) Int. Cl. H03F 3/08

(52) U.S. Cl. 330/2; 330/308

(57) ABSTRACT

An injection current test circuit for an amplifier (24) includes a test current input pad (16). One (14) of a plurality of current mirrors (12) is connected to the test current input pad (16). A switch (20) is connected to a second (18) of the plurality of current mirrors (12) and connected to the amplifier (24). A test current output pad (22) is connected to the switch (20).

### FIELD OF THE INVENTION

The present invention relates generally to the field of test circuits and more particularly to an injection current test circuit.

### BACKGROUND OF THE INVENTION

Integrated circuits are difficult to test after they have been packaged. For instances, testing an optical preamplifier requires two parameters be evaluated. The first parameter that needs to be evaluated is the efficiency (responsivity) of the photo-detector. The second parameter is the amplifier gain and bandwidth performance. Since a complete photo-detector receives light as an input and generates a voltage as the output it is not possible to separate the photo-detector responsivity from the gain of the amplifier.

Thus there exists a need for a current injection test circuit that can determine amplifier gain and bandwidth performance separate from the photo-detector's performance.

### BRIEF DESCRIPTION OF THE DRAWINGS

FIG. 1 is a block diagram of an injection current test circuit for an amplifier in accordance with one embodiment of the invention;

FIG. 2 is a block diagram of an injection current test circuit for an amplifier in accordance with one embodiment of the invention; and

FIG. 3 is a schematic diagram of an injection current test circuit for an amplifier in accordance with one embodiment of the invention.

### DETAILED DESCRIPTION OF THE DRAWINGS

An injection current test circuit for an amplifier includes a test current input pad. One of a plurality of current mirrors is connected to the test current input pad. A switch is connected to a second of the plurality of current mirrors and connected to the amplifier. A test current output pad is connected to the switch. In one embodiment, the photo-detector is connected between the amplifier and one of the current mirrors. This allows the circuit to determine if photo-detector is conducting. The current mirrors provide isolation between the input current and the amplifier, which provides for more accurate testing of the amplifier. By modulating the input current the bandwidth of the amplifier can be tested. Note that the test circuit and amplifiers are particularly useful when they are incorporated into an integrated circuit.

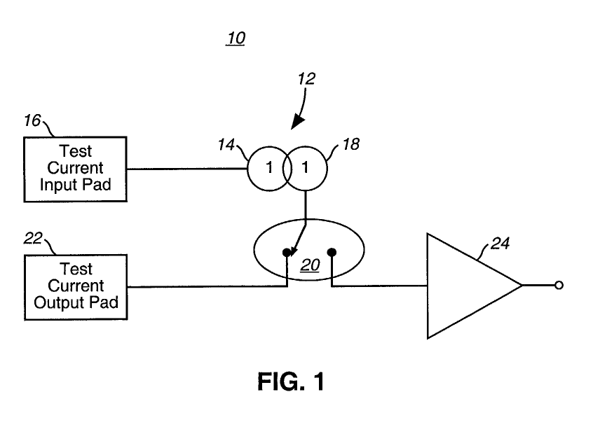

FIG. 1 is a block diagram of an injection current test circuit 10 for an amplifier in accordance with one embodiment of the invention. The circuit includes a plurality of current mirrors 12. One 14 of the plurality of current mirrors 12 has an input connected to a test current input pad 16. An output of a second 18 of the plurality of current mirrors 12 is connected to a switch 20. The switch 20 has a first output that is connected to the test current output pad 22 and a second output that is connected to the amplifier 24. The test current is used to test the amplifier and the switch allows the test current to be measured.

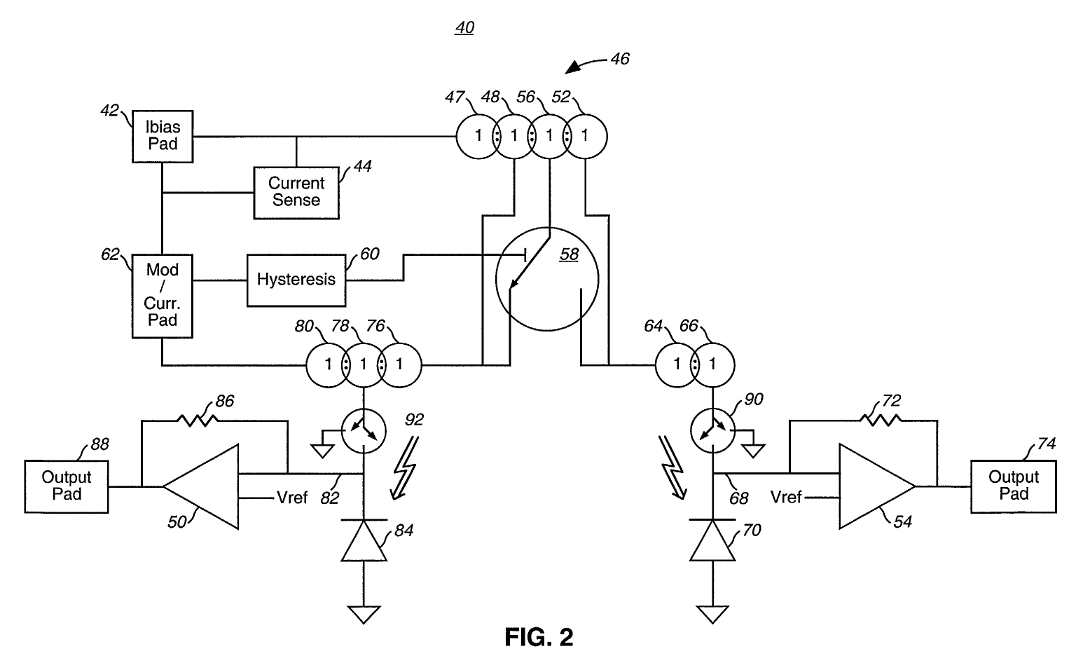

FIG. 2 is a block diagram of an injection current test circuit 40 for an amplifier in accordance with one embodiment of the invention. The circuit 40 has a current input 42 connected to a current sense circuit 44. When the current sense circuit 44 does not detect any current it drives the input 42 high or to a disabled state. The input 42 is connected to a plurality of current mirrors 46. One 47 of the plurality of current mirrors 46 is connected to the input test pad 42. A second 48 of the plurality of current mirrors is used to drive a first amplifier 50 a second 52 of the plurality of current mirrors 46 is used to drive a second amplifier 54. A third 56 of the current mirrors is connected to switch (modulation switch)58. The switch 58 connects the current mirror 56 to either the first amplifier 50 or to a second amplifier 54. The switch 58 is connected to a hysteresis circuit 60. The hysteresis circuit 60 is connected to a modulation pad (test current output pad) 62. The hysteresis circuit 60 drives the voltage to a high state or a low state and does not allow the input current to the switch 58 to be in-between the two output states. For instance the if the input voltage to the hysteresis circuit 60 is less than 1.5 volts the output of the hysteresis circuit 60 is low. When the voltage starts to rise at the modulation input 62, the hysteresis circuit's output will be low until the input voltage 62 is at least 3.5 volts. Then the output of the hysteresis circuit's output will go high. The reverse is true as the input voltage 62 begins to drop, the hysteresis circuit 60 will not change to a low state until the voltage drops to 1.5 volts. The exact thresholds can obviously be varied according to the designer's needs. The modulation pad 62 is connected to the current sense circuit 44. When the current sense circuit 44 does not sense an input current on pad 42, then the current sense circuit 44 drives the modulation input pad 62 low or to a disabled state.

The amplifier 54 is connected to the current mirror 52 through a pair of current mirrors 64, 66. The current mirror 66 is connected to an input 68 of the amplifier 54. A photo-detector 70 is also connected to the input 68. A feedback resistor 72 is connected between an output 74 of the amplifier 54 and the input 68 of the amplifier 54. The amplifier 40 is connected to current mirror 48 by three current mirrors 76, 78, 80. The three current mirrors 76, 78, 80 form a second plurality of current mirrors. The current mirror 78 is connected to an input 82 of amplifier 50. A photo-detector 84 is also connected to the input 82. A feedback resistor 86 is connected between an output 88 of the amplifier 50 and the input 82 of the amplifier 50. Another current mirror 80 is connected to the modulation pad (current sense pad) 62. Note that test switch (isolation switch) 90 & 92 are used to connected the amplifiers 50 & 54 alternatively between ground and the current mirrors 66 & 78. The test switch can be formed by a pair of transistors.

When a highly accurate DC current is applied to the input pad 42, it can be measured on the current sense pad 62. This requires setting the switch to connect current mirror 56 to amplifier 54. This allows highly accurate testing of the input current. By sensing the output at output pad 74 & 88 the amplifier gain can be accurately tested. When a modulation signal is applied to the modulation input 62, the input to the amplifiers 50, 54 vary from two times the input current to the input current. By measuring the outputs 74, 88 of the amplifiers 50, 54 the bandwidth performance of the amplifiers can be accurately determined. The current sense circuit 44 keeps the test input pads 42 & 62 from floating and introducing performance degradations into the circuit. This is accomplished with just two pads when it would normally require at least three pads on the integrated circuit.

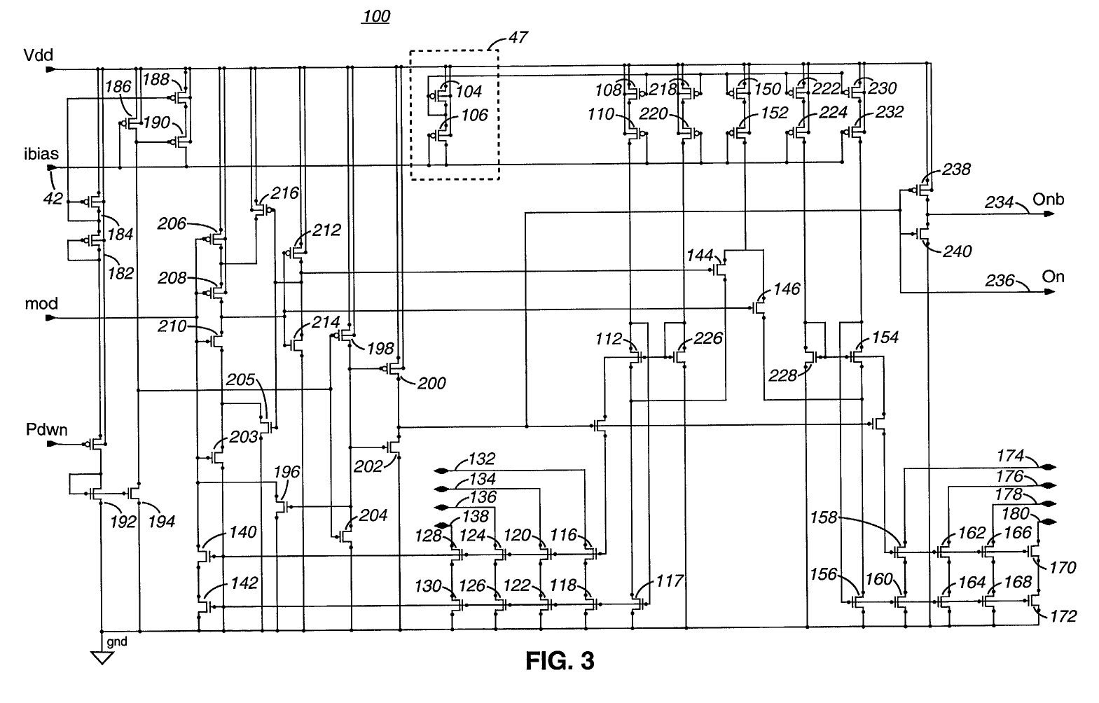

FIG. 3 is a schematic diagram of an injection current test circuit 100 for an amplifier in accordance with one embodiment of the invention. The schematic diagram is similar to FIG. 2 but does not show the amplifiers and photo-detectors. In addition, the circuit 100 is setup to drive eight amplifier/photo-detector combinations. The current input pad 42 is connected to a current mirror 47 formed by transistors 102 & 104. Current mirror 47 is part of the first plurality of current mirrors 46 (FIG. 2). Transistors 108 & 110 form current mirror 48. The transistors 112 & 114 form current mirror 76 (FIG. 2). The current mirror 78 (FIG. 2) is represented by four current mirrors since the circuit is designed to drive eight photo-detector/amplifier pairs. These current mirrors are formed by transistor pairs 116 & 118; 120 & 122; 124 & 126; 128 & 130. The outputs 132, 134, 136, 138 of the current mirrors are connected through a photo-detector to an input of an amplifier. The current mirror 80 (FIG. 2) is formed by transistor pair 140 & 142.

The switch 58 (FIG. 2) is formed by the transistors 144 & 146. The switch 58 is connected to the current mirror 56 (FIG. 2) which is formed by transistors 150 & 152. The switch 58 connects the current mirror 56 (FIG. 2) either to current mirror 76 formed by transistors 112 & 114 or to current mirror 64 (FIG. 2) formed by transistors 154 & 156. The current mirror 66 (FIG. 2) is represented by four current mirrors since the circuit is designed to drive eight photo-detector/amplifier pairs. These current mirrors are formed by transistor pairs 158 & 160; 162 & 164; 166 & 168; 170 & 172. The outputs 174, 176, 178, 180 of the current mirrors are connected through a photo-detector to an input of an amplifier.

The current sense circuit 44 (FIG. 2) is formed by several groups of transistors. One group of these transistors includes transistors 182, 184, 186, 188, 190. A second group of these transistors includes transistors 192, 194, 196, 198, 200, 202, 203, 204, 205. The hysteresis circuit 60 (FIG. 2) is formed by transistors 206, 208, 210, 212, 214, 216. Reference voltages are formed by the transistors 218, 220; and 222 & 224. These reference voltages are also controlled by transistors 226, 228. The current mirror 52 (FIG. 2) is formed by transistors 230 & 232. The test switch 90 is controlled by the outputs (on, onb) 234, 236 that are driven by transistors 238, 240.

Thus there has been described an injection current test circuit that can determine amplifier gain and bandwidth performance separate from the photo-detector's performance. This is accomplished without jeopardizing the performance on the amplifier circuit being tested during standard operation. This circuit allows loop back testing of the input current and modulation of the input current while only requiring two pad on the integrated circuit.

While the invention has been described in conjunction with specific embodiments thereof, it is evident that many alterations, modifications, and variations will be apparent to those skilled in the art in light of the foregoing description. Accordingly, it is intended to embrace all such alterations, modifications, and variations in the appended claims.

What is claimed is:

1. An injection current test circuit for an amplifier, comprising:
a test current input pad;
a plurality of current mirrors, one of the plurality of current mirrors connected to the test current input pad;
a switch connected to a second of the plurality of current mirrors and connected to the amplifier; and
a test current output pad connected to the switch.

2. The circuit of claim 1, further including a current sense circuit connected to the test current input pad.

3. The circuit of claim 2, wherein the current sense circuit drives the test current input pad to a disabled state when no current is detected.

4. The circuit of claim 1, further including a hysteresis circuit having an input, the hysteresis circuit having an output that drives the switch.

5. The circuit of claim 1, further including a photo-detector connected between a third of the plurality of current mirrors and the input of the amplifier.

6. The circuit of claim 5, further including a test switch having a first state that connects the photo-detector to the second of the plurality of current mirrors and a second state that connects the photo-detector to ground.

7. The circuit of claim 6, wherein the test switch comprises a pair of transistors.

8. The circuit of claim 7, further including a pair of current mirrors connected between the test switch and the second of the plurality of current mirrors.

9. The circuit of claim 5, wherein an input test current flows through the photo-detector to the input of the amplifier.

10. An injection current test circuit for an amplifier, comprising:
a plurality of current mirrors, one of the plurality of current mirrors having an input connected to a test current input;
a switch connected to an output of a second of the plurality of current mirrors;
a hysteresis circuit connected to a modulation input and having an output that drives the switch; and
the amplifier having an input connected to the switch.

11. The circuit of claim 10, further including a second plurality of current mirrors, one of the second plurality of current mirrors connected to the switch.

12. The circuit of claim 11, wherein a second of the second plurality of current mirrors has an output connected to the input of the amplifier.

13. The circuit of claim 12, wherein a third of the second plurality of current mirrors has an output connected to the modulation input.

14. The circuit of claim 13, further including a photo-detector between the one of the second of the plurality of current mirrors and the input of the amplifier.

15. The circuit of claim 14, further including an isolation switch between the photo-detector and the input of the amplifier.

16. An injection current test circuit for an amplifier, comprising:
a hysteresis circuit connected to a modulation input and having an output;
a modulation switch controlled by the output of the hysteresis circuit, the modulation switch having a test current input and an output that is connected to the amplifier in a first state; and
a current sense circuit connected the test current input.

17. The circuit of claim 16, wherein the current sense circuit drives an input of the hysteresis circuit low when no current is detected.

18. The circuit of claim 16, further including a plurality of current mirrors having an input connected to the test current input and an output connected to the modulation switch.

19. The circuit of claim 18, further including a second plurality of current mirrors connected between the modulation switch and the amplifier.
